(19) United States
(12) Patent Application Publication
(10) Pub. No.: US 2012/0055633 A1
(43) Pub. Date: Mar. 8, 2012

(54) HIGH THROUGHPUT PHYSICAL VAPOR DEPOSITION APPARATUS AND METHOD FOR MANUFACTURE OF SOLID STATE BATTERIES

(75) Inventors: Hyoncheol KIM, Ann Arbor, MI (US); Marc LANGLOIS, Ann Arbor, MI (US); Myoungdo CHUNG, Ann Arbor, MI (US); Ann Marie SASTRY, Ann Arbor, MI (US)

(73) Assignee: Sakti3, Inc., Ann Arbor, MI (US)

(21) Appl. No.: 13/292,368

(22) Filed: Nov. 9, 2011

(51) Int. Cl. C23C 16/448; C23C 16/56; C23F 1/08; C23C 16/52

(52) U.S. Cl. 156/345.39; 118/726; 118/697; 118/712; 118/688; 118/720; 156/345.1; 156/345.4

(57) ABSTRACT

An apparatus for formation of element(s) of an electrochemical cell using a complete process. The apparatus includes a first work piece configured to a transfer device, a source of material in fluid form, a reaction region operably coupled to the source of material and a second work piece configured within a vicinity of the reaction region. The apparatus also has an energy source configured to the reaction region to subject a portion of the material to energy to substantially evaporate the portion of the material within a time period and cause deposition of a gaseous species derived from the evaporated material onto a surface region of the second work piece to form a thickness of material for a component of the solid state electrochemical device and a vacuum chamber to maintain at least the first and second work pieces, the reaction region, and the material within a vacuum environment.

### CROSS-REFERENCES TO RELATED APPLICATIONS

The present application incorporates by reference, for all purposes, the following pending patent applications: U.S. application Ser. No. 12/484,966 filed Jun. 15, 2009, and titled METHOD FOR HIGH VOLUME MANUFACTURE OF ELECTROCHEMICAL CELLS USING PHYSICAL VAPOR DEPOSITION, commonly assigned; and U.S. application Ser. No. 12/484,959 filed Jun. 15, 2009, titled COMPUTATIONAL METHOD FOR DESIGN AND MANUFACTURE OF ELECTROCHEMICAL SYSTEMS, commonly assigned.

### BACKGROUND OF THE INVENTION

This present invention relates to manufacture of electrochemical cells. More particularly, the present invention provides an apparatus and method for manufacturing a solid state thin film battery device. Merely by way of example, the invention has been described with the use of lithium based cells, but it is recognized that other materials such as zinc, silver, copper, cobalt, iron, manganese, magnesium and nickel could be designed in the same or like fashion. Additionally, such batteries can be used for a variety of applications such as portable electronics (cell phones, personal digital assistants, music players, video cameras, and the like), power tools, power supplies for military use (communications, lighting, imaging and the like), power supplies for aerospace applications (power for satellites), and power supplies for vehicle applications (hybrid electric vehicles, plug-in hybrid electric vehicles, and fully electric vehicles). The design of such batteries is also applicable to cases in which the battery is not the only power supply in the system, and additional power is provided by a fuel cell, other battery, IC engine or other combustion device, capacitor, solar cell, etc.

It is well known that complex metal oxides can be suitable for solid state lithium ion batteries, however; it is also known that these same materials, for the most part, cannot be economically vacuum deposited for a number of fundamental reasons. First is that they, like all alloys and complex compounds, have components that will evaporate at different rates due to different elemental vapor pressures, leading to a significant change between the starting material and the deposited film. Additionally, many of these compounds degrade or decompose (e.g., become something that does not evaporate) upon heating below their vapor pressure, even in very low vacuum environments. Decomposition will also lead to unwanted deposited film stochiometery and will significantly reduce the amount of starting material that can be successfully deposited. This leads to large amounts of waste remaining in the deposition source changing and hindering further deposition. High rates are also limited because simply increasing the area of evaporant or evaporation temperature also increases these issues. Finally, in order to be economical, long deposition runs and large areas of electrochemical device material must be coated in each vacuum cycle. Simply using large pots, containers, etc. of these materials only exacerbate these problems.

Accordingly, it is seen that there exists a need for an apparatus and method to produce an improved film(s) for a large scale, high capacity solid state battery.

### BRIEF SUMMARY OF THE INVENTION

According to the present invention, apparatus related to manufacture of electrochemical cells are provided. More particularly, the present invention provides an apparatus and method of manufacturing a solid state thin film battery device. Merely by way of example, the invention has been provided with use of lithium based cells, but it would be recognized that other materials described above, could be designed in the same or like fashion. Additionally, such batteries can be used for a variety of applications such as portable electronics (cell phones, personal digital assistants, music players, video cameras, and the like), power tools, power supplies for military use (communications, lighting, imaging and the like), power supplies for aerospace applications (power for satellites), and power supplies for vehicle applications (hybrid electric vehicles, plug-in hybrid electric vehicles, and fully electric vehicles). The design of such batteries is also applicable to cases in which the battery is not the only power supply in the system, and additional power is provided by a fuel cell, other battery, IC engine or other combustion device, capacitor, solar cell, etc.

In a specific embodiment, the present invention provides an apparatus for formation of one or more elements of an electrochemical cell using a complete process. The apparatus includes a first work piece configured to a transfer device, a source of material in fluid form, a reaction region operably coupled to the source of material in fluid form, and a second work piece configured within a vicinity of the reaction region. The apparatus also has an energy source configured to the reaction region to subject a portion of the material to energy to substantially evaporate the portion of the material within a time period and cause deposition of a gaseous species derived from the evaporated material onto a surface region of the second work piece to form a thickness of material for a component of the solid state electrochemical device and a vacuum chamber to maintain at least the first and second work pieces, the reaction region, and the material within a vacuum environment.

In a specific embodiment, the present invention provides an apparatus for the manufacture of a solid state electrochemical device using a high speed evaporation process. The apparatus includes a containment vessel for a metal oxide or other material, which is characterized in a fluid, bendable, meter-able, or dispensable form and characterized by an engineered surface to volume ratio. The apparatus also includes a hot wall reactor region coupled to the containment vessel by a transport mechanism and a process region positioned within a vicinity of the hot wall reactor region. Apparatus also includes a work piece provided within the process region and coupled to a transfer device configured to move the work piece from a first region to a second region in a continuous or intermittent manner. The process region is within a vicinity of the hot wall reactor to expose the work piece to the hot wall reactor in a specific embodiment. The vicinity of the reactor is provided between the hot wall reactor and the work piece is about 10 cm to 1 meter. The apparatus also includes a vacuum chamber or plurality of chambers in fluid communication with each other. The vacuum chamber is configured to enclose the containment vessel, hot wall reactor region, process region, and the work piece within the process region. The apparatus also includes an energy source configured to the hot wall reactor to subject the material to thermal energy to substantially evaporate the material within a time period of about one second or less without decomposition into undesirable components and cause deposition of a desired gaseous species derived from the evaporated material onto a surface region of the work piece to form the cathode or cathode modification component (e.g., carbon, metal, semiconductor, insulator, additive, dopant, impurity, chemical, alloying component, diffusivity enhancement component, resistivity component) of the solid state electrochemical device. Other materials such as cathode, electrolyte, and combinations, and the like may also be deposited using the present apparatus. Of course, there can be other variations, modifications, and alternatives.

In an alternative specific embodiment, the present invention provides an apparatus for formation of one or more elements of an electrochemical cell using a complete process. The apparatus includes a first work piece configured to a transfer device and a source of material in fluid form. The source of material coupled to the first work piece. The apparatus includes a reaction region operably coupled to the source of material in fluid form and a second work piece configured within a vicinity of the reaction region. The apparatus includes an energy source configured to the reaction region to subject a portion of the material to energy to substantially evaporate the portion of the material within a time period and cause deposition of a gaseous species derived from the evaporated material onto a surface region of the second work piece to form a thickness of material for a component of the solid state electrochemical device. The apparatus also includes a vacuum chamber to maintain at least the first and second work pieces, the reaction region, and the material within a vacuum environment. Again, there may be variations.

Benefits are achieved over conventional techniques. Depending upon the specific embodiment, one or more of these benefits may be achieved. In a preferred embodiment, the present invention provides an apparatus for complete deposition of electrochemical cell materials, including anode, cathode, electrolyte, current collectors, and barriers, including combinations thereof using, for example, a reel to reel or drum configuration, which forms a solid state thin film electrochemical cell that is configured in a roll or roll-like manner. The complete deposition occurs in a continuous or semi-continuous manner to form a plurality of individual cells, which are stacked on top of each other in either serial or parallel or a combination of these configurations. Specific benefits seen over the current art include:

a) The ability to continuously supply sufficient deposition material to the evaporation source to deposit suitable films of significant thickness (between about 0.1 micron and several microns) on large areas without changes in deposition conditions, rates, or quality.

b) A complete decoupling of the deposition rate from the temperature of the evaporation source. In conventional evaporation sources, a charge of evaporant material is placed in the unit. When the source reaches evaporation temperature, the material begins to convert from a solid to a vapor. It is well known that this relationship between evaporation temperature and evaporation rate is very non-linear, that is, a small change in temperature will cause a large change in evaporation rate. Therefore, because this invention keeps the evaporation source (hot wall reactor) at a relatively fixed temperature, and varies the deposition rate by the feed rate of material into the source, it is able to not only easily vary the evaporation (or deposition) rate but to keep it constant for long periods of time.

c) By virtue of this decoupling, one or more delivery sources or full deposition sources may be linked or operated in conjunction to produce mixed depositions of materials normally not evaporable from a single source with all of the above benefits.

d) Additionally, by virtue of this decoupling, graded films are easily produced, consistent over long periods of time and large areas.

e) Specifically, films with a linear or non-linear varying amount of evaporants “A” and “B” through the thickness of the film may be produced, By way of example, two evaporant streams are here discussed, but this principle may be applied to any number of streams of evaporant materials, even including repeating layers of non-miscible or non-alloying evaporant materials.

f) It is further understood that the evaporant material itself may be a combination or mixture of one or more materials.

g) By proper computation of the surface to volume ratio with the vapor/temperature/pressure function of the material, powder of various sizes are suitable up to and including powder sufficiently large in size to be essentially wire, and up to liquids.

h) Additionally, the unique feature of mass balance with fixed evaporation temperature allows other apparatus or means to be successfully incorporated into the deposition of these thin film electrochemical cells. Specifically included are the apparatus for depositing films of various modulus, and/or residual stresses. These apparatus include but are not limited to shadow masking and oblique angle deposition, selective removal of non miscible materials co-deposited or consecutively deposited, ablation or removal (such as by plasma or ion etching) or entraining non reactive materials, such as nano rods, nano spheres, cones, tubules and the like with and without binders.

i) Additionally, the multi deposition of cathode and anode in a single layer is also possible by the invention. Specific elements include deposition of cathode materials with some or all of a stochiometric amount of anode material. Advantages have been shown to include the ability to deposit substantially smoother layers, especially in the case of lithium metal which is not favored to deposit into smooth films, and the ability to produce substantially safer devices which are partially or fully discharged.

j) Additionally, as incorporated into the claims of this invention, the ability to deposit films such as above has proven to result in substantially lower levels of intercalation stress of anode materials into cathode materials by their co-deposit.

Depending upon the specific embodiment, one or more of these benefits may be achieved. Of course, there can be other variations, modifications, and alternatives.

The present invention achieves these benefits and others in the context of known process technology. It is also clear that embodiments of the invention may be optimized or changed for evaporant materials of different surface to volume ratio; however, the intrinsic invention and its purpose are conserved.

The present invention, though non-intuitive, has shown to address the majority of these problems. By taking learning from the chemical industries use of hot wall reactors, and decreasing the time the material to be deposited is subjected to heat, while increasing the surface to volume ratio of the evaporant, it has proven possible to reduce the residual non-stochiometric and non-vaporizable portion of the starting material by over 80%. Also, by carefully controlling the temperature of the evaporation surface, it is possible to significantly increase the rate of deposition without the detrimental process conditions seen with current technology. Further, since the evaporant time at temperature has been limited to the sub-second range, it is possible to supply a constant flow of these high surface-to-volume ratio materials from a central reservoir essentially providing a fresh source of evaporant material uncontaminated by heating. Finally, to allow long runs, now possible by this invention, it has been shown that the deposition material reservoir may be provided with the proper valves and fittings to allow refilling from outside of the vacuum tool without stopping the processing inside of the tool.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

The following diagrams are merely examples, which should not unduly limit the scope of the claims herein. One of ordinary skill in the art would recognize many other variations, modifications, and alternatives. It is also understood that the examples and embodiments described herein are for illustrative purposes only and that various modifications or changes in light thereof will be suggested to persons skilled in the art and are to be included within the spirit and purview of this process and scope of the appended claims.

FIG. 1 illustrates a simplified diagram of an evaporant-delivering device according to an embodiment of the present invention.

FIG. 2 illustrates a simplified diagram of an evaporant-delivering device according to an embodiment of the present invention.

FIG. 3 illustrates a simplified diagram of an evaporant-delivering device according to an embodiment of the present invention.

FIG. 4 illustrates a simplified diagram of an evaporant-delivering device according to an embodiment of the present invention.

### DETAILED DESCRIPTION OF THE INVENTION

According to the present invention, apparatus related to manufacture of electrochemical cells are provided. More particularly, the present invention provides an apparatus and method of manufacturing a solid state thin film battery device. Merely by way of example, the invention has been provided with use of lithium based cells, but it would be recognized that other materials described above, could be designed in the same or like fashion. Additionally, such batteries can be used for a variety of applications such as portable electronics (cell phones, personal digital assistants, music players, video cameras, and the like), power tools, power supplies for military use (communications, lighting, imaging and the like), power supplies for aerospace applications (power for satellites), and power supplies for vehicle applications (hybrid electric vehicles, plug-in hybrid electric vehicles, and fully electric vehicles). The design of such batteries is also applicable to cases in which the battery is not the only power supply in the system, and additional power is provided by a fuel cell, other battery, IC engine or other combustion device, capacitor, solar cell, etc.

One element of the invention relates to the ability to continuously feed deposition material to the hot wall reactor. Due to the unique feature of separating the storage of evaporant material from metering the evaporant material and then transporting the evaporant material to the evaporation source, it is possible to have an extended quantity of material stored in a storage container without degradation or contamination. The evaporant in the storage container may be a mixture of materials for co or multi evaporation. This storage container may be located either inside or outside of the vacuum coating system as described later. Bulk storage of material varies from very fine powders (micron size particles) to large particles, to rods or spheres to liquids; each calculated to perform a distinct mass balance between delivery and evaporation at the required deposition rate. By means of illustration, common evaporation sources contain storage for materials from several grams to several 10's of grams while the invention allows storage and unrestricted use of several Kilo Grams of material. Means to accomplish this include hoppers for powders, spools for wire, cassettes for rods or tubes, and heated vessels for liquids. To allow the stated goal of low cost manufacturing, even greater amounts of material may be introduced continuously to the hot wall reactor via a series of vacuum gates and load locks allowing feeding or refilling of the storage container while the deposition progresses undisturbed.

A further element of the invention pertaining to external filling is the ability and desire to condition the deposition material or evaporant prior to introducing it to the hot wall reactor. This may be accomplished by utilizing one or more of the vacuum gates and load locks described above, to subject the material to heat and/or vacuum to accomplish the desirable function of degassing and/or pre heating the material to assist in the high quality and defect free deposition and film growth desired.

A further element of the invention, made possible by the above feature of complete separation of evaporant storage and vaporization is the ability to vary the deposition rate without varying the evaporation temperature. As described previously, one of the main problems with conventional technology is the decomposition of certain desirable evaporant materials upon heating, including heating below their vaporization temperature. A second problem with conventional technology is the strong interaction in evaporation rate with temperature. This rate is non linear. The undesirable result being that a small change in evaporator temperature will result not only in a large change in evaporation rate (with all of the difficulties of thickness and morphology control of the resultant film) but also the large change in stochiometery of the deposited film.

Particularly true in the case of mixed metal oxides necessary for the electrochemical device made by the invention, small changes in any of the constituents, or even of the oxidation states of the constituents will have large, detrimental results on the efficiency and value of the device.

Thus, by this element of the invention, it is now possible to fix the temperature of the hot wall reactor thus controlling the stochiometery of the delivered evaporant, and fixing or varying as required the delivery rate of the evaporant by varying the delivery of material from the storage unit to the hot wall reactor.

Secondary benefits of this element, not seen in current technology, include the ability to shape the delivery plume of vaporized material to fit the size and uniformity needs of the substrate. This significant feature can and does result in substantial savings not only of material, but also of reclaim or cleaning services and other handling and contamination of the vacuum deposition device, thus allowing longer un-interrupted runs resulting in higher yield at lower cost. This shaping or control of the deposition plume is particularly beneficial when depositing modified modulus layers, such a voided or porous materials.

Temperature control and stability of the hot wall reactor may be accomplished by any number of means such as resistance heating with feedback, induction heating with feedback, heating by bombardment of a portion of the hot walled reactor with energetic particles such as ions or electrons. Feedback is not limited to being provided by thermocouples, infar red radiation, changes in oscillation of a crystal resonant circuit, and the like.

Transport of the evaporant to the hot wall reactor may be accomplished by any number of means and must be specifically tailored to each materials surface to volume ratio and mechanical constraints. Mechanical constraints making this task difficult to accomplish include, but are not limited to, powder fluid mechanic issues with high surface to volume ratio materials in a vacuum environment coalescing into larger, difficult or impossible to move clumps. In addition, any significant clumping or granularization of engineered powders will render the mass balance between vaporization and supply inoperable, causing the device to fail. Specific elements of the invention to successfully transport evaporant material include endless metal belts of materials non reactive with the particular evaporant material, screw conveyors, drop buckets, weight balanced tip carts, volume balanced tip carts, waterfall units with and without a weir, revolving wheels with and without pockets, such as gravure pockets, and the like.

A unique element of the invention is the non-intuitive need to control the size and cohesion of evaporant particles during transport. This is due to the changing nature of mechanical properties experienced especially by powders under vacuum and/or heating. Key elements of modifying transport means for this invention include, but are not limited to, coatings on the transport materials that modify the surface tension to allow stable transport and allow controlled release, electrostatic attraction or force, magnetic attraction or force, compression, sonic vibration, ultrasonic vibration, periodic compression (such as forming discrete compressed volumes such as pills or the like).

Another element of the invention is the ability to couple multiple evaporation sources, like hot wall reactors, with a single storage-metering-delivery unit; thus allowing longer pre-loaded volumes of evaporant materials. Conversely it is possible with this invention to couple different storage units to a single evaporation source thus allowing multiple layers of different materials to be deposited from a single location which has beneficial attributes of equipment size, capital cost, and substantial technical benefit for masking or delineating layers into electrochemical devices-in particular modulus adjusted layers such as voided or porous materials.

Yet another novel element of the invention is the ability to utilize two or more disparate or individually configured apparatuses to multi-deposit significantly different materials which are not compatible with co deposition from a single unit. Examples in electrochemical devices such as batteries include the multi deposition of cathode and anode chemistries. These chemistries include, but are not limited to layers of vanadium, cobalt, nickel, iron, aluminum, magnesium, lithium, lithium alloys, silicon-lithium compounds, phosperous, phosphates, phosphides, lithiates, sulphides, sulphates, and the like.

Yet another novel element of the invention is the ability to cost effectively manufacture a wide variety of functionally graded materials inherent in the inventions ability to vary deposition rate without changing deposition temperature. Examples enabled by the invention include, but are not limited to, varying the amounts of cathode to anode material throughout the thickness of a combination or multi-deposited depleted cathode layer, graded index or modulus films for the control and tailoring of stress or temperature and the control of their gradients.

Yet a further novel element of the invention is the ability to entrain or co or multi deposit inert materials along with active materials to manufacture unique combination materials possessing useful properties. Examples for the manufacture of electrochemical devices such as batteries include, but are not limited to, the inclusion of nano or micro sized particles of ceramics, glasses, plastics, and the like in order to modify not only the modulus or physical and mechanical properties of the deposited film, but allow a fundamental change in their structure, such as selective removal, after deposition, of one or more of these inert compounds by chemical, thermal, or plasma etching means. One example for the manufacture of electrochemical devices such as batteries is the manufacture of a micro or macro porous film or “anode region” to allow the accumulation of anode materials, such as lithium, under charged or changing states of charge (SOC) by providing a multitude of voids while retaining mechanical stability and electrical conductivity.

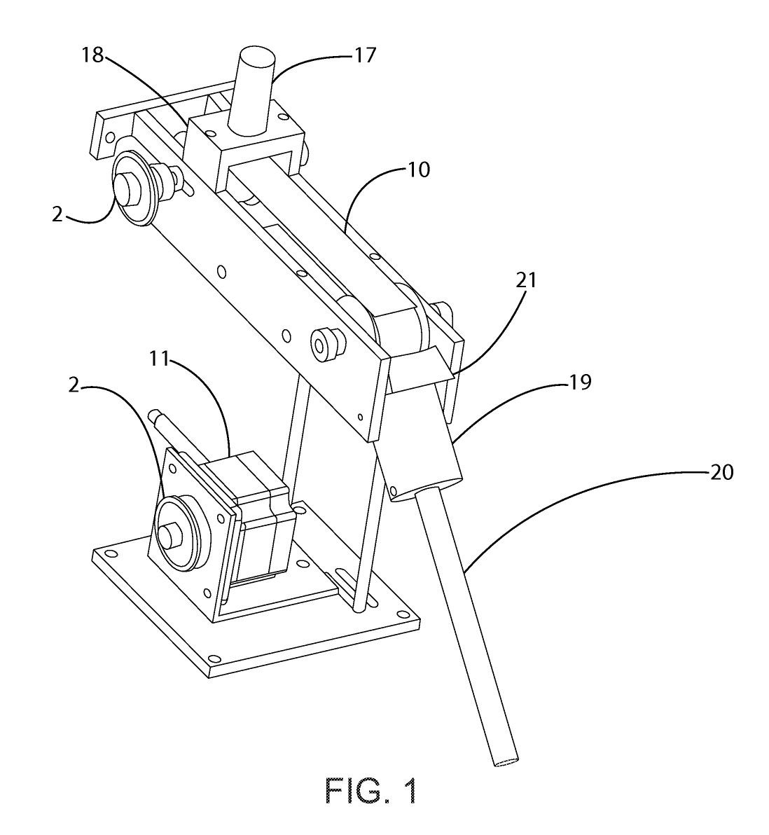

As further described and illustrated in FIG. 1, the elemental steps provided by this invention are as follows:

FIG. 1 illustrates a simplified diagram of an evaporant-delivering device according to an embodiment of the present invention.

Referring to FIG. 1, describing a preferred embodiment of the invention particularly unique and useful for delivering evaporant material whose calculated surface to volume ratio is extremely large. As can be seen in FIG. 1, item 10 consists of an endless metal belt configured between rollers driven by items 2 and 11. Of course, there can be other variations, modifications, and alternatives.

For purposes of illustration, a stepping motor is shown, but any means of motion is considered in the invention including DC, and AC motors in their various configurations (including servo with and without feedback) as well as external to the vacuum chamber mounted motors driving the belt via shafting, gears, pulleys, belts and the like.

Thus, item 10 may be driven in a direction to move towards the delivery end of the invention characterized by item 20, the directing tube. Looking now at items 17 & 18, it can be seen where this invention connects to the large storage container previously described in detail. Now, in order to deliver a known quantity of evaporant material at a consistent rate, the evaporant material must be metered onto the belt. Many means for metering were attempted without success (success being measured in part by non-clogging, non-compacting and consistent delivery of >1 kg of evaporant material). Unknown to work and an element of the invention, was the use of a variable weir at the exit of the tube 17 connecting to the belt 10 where the action of the belt is harnessed to churn the evaporant and to provide a controlled forward motion of the evaporant (in this case a very fine powder) towards the weir.

In this way, there is a controllable force applied to the evaporant to insure its consistent movement. It is, however, not sufficient to use a weir of conventional technology, characterized by controlling flow over or thru its opening. In order to place the evaporant material in a predetermined location on the belt 10 and in an amount and in a consistency sufficient for manufacture of the product, a doctor blade must also be employed. The other unique portions of the invention of this embodiment include a second doctor blade 21 which scrapes the belt 10 after the majority of material has left the belt and entered into the directing tube 20. This second blade insures that all metered material is delivered to the evaporation source, and the belt is clean and ready for further use. Additionally, in this embodiment of the invention, there are designed into the apparatus adjustability in belt tension, belt speed, weir size and shape, and the size, shape, angle of attack, and pressure of the two doctor blades. As can easily be envisioned, once these unique elements of the invention are incorporated into an apparatus, various modifications to the apparatus may be made without compromise of the uniqueness of the invention. These modifications include size and shape of the weir and doctor blades, length and width of the belt, angle and length of the directing tube, and its placement inside of the vacuum chamber. It is important to note that the elements presented by this apparatus in combination with each other and in combination with the delivery of large quantities of evaporant material useful for solid state electrochemical devices are unique in this industry and not commercially available, and thus needed to be invented.

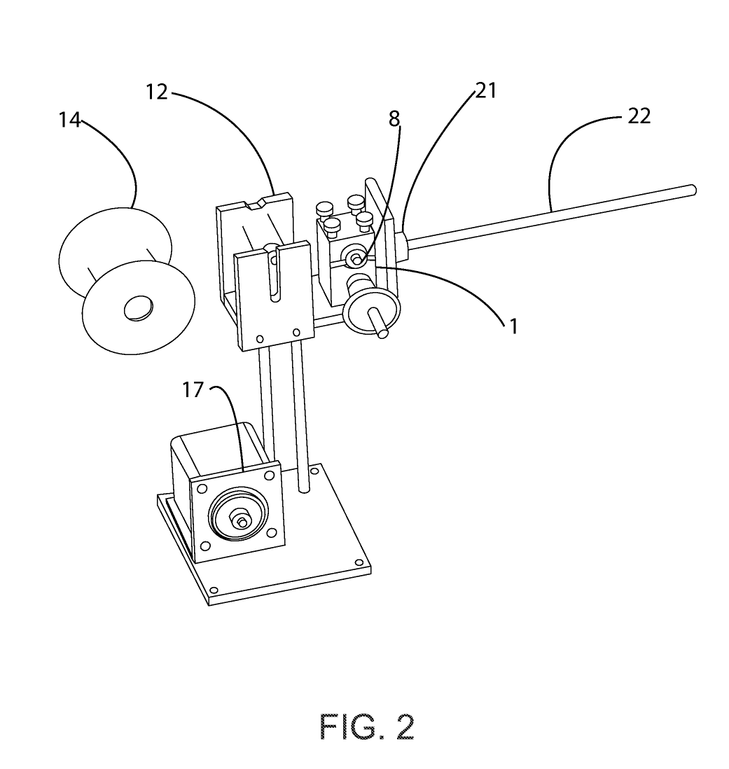

FIG. 2 illustrates a simplified diagram of an evaporant-delivering device according to an embodiment of the present invention.

Referring to FIG. 2, describing a preferred embodiment of the invention particularly unique and useful for delivering evaporant material whose calculated surface to volume ratio is relatively small. As can be seen in figure two, this embodiment contains many elements common to figure one, in particular, the use of a motor 17 and means of driving rotating elements 8. Again, in this embodiment, rotary motion components encompass AC and DC motors, stepper motors, both inside and outside of the vacuum environment. Unique to this embodiment are the rotating wheels held inside of pressure block 1. As illustrated, these two wheels are mounted in individual housing but held in close alignment by shoulder bolts, dowel pins, drill rod, and the like, with and without bushings. These two housings are held in contact with each other by compression springs mounted as illustrated around the shoulder bolts, but as can be envisioned, other means of applied force, such as torsion springs, extension springs, weights, pressure in cylinders or bellows, etc. can be used. The purpose of the pressure is to balance the gripping or motive force of the motor driven lower wheel with the evaporant, in this case, in the shape of a long and relatively thin bar or wire. Integral to the invention is the incorporation of evaporant material in bar, tube, pipe or wire form. Particularly, a hollow form of Material A filled with Material B for co-deposition. Material B could be a liquid, powder, or solid material, and could also be reactive or catalyzing.

Moving farther down the apparatus, you will notice the evaporant holder 14 in this embodiment, a reel. Other elements of this embodiment include, but are not limited to, nested evaporant fed either from the inside or outside of the nest, bundles of sticks of material either in a magazine, rotary cylinder, or attached to a flexible or non-flexible substrate such as seen in tape and reel electronic placement machines, or belts for automatic screw guns.

Of particular note is the need, unrecognized until after many alterations, for feedback or holding force, of a particular level, on the magazine, or source of evaporant. This is accomplished by the precise contact between reel 14 and holder 12 and the mass of the parts, as shown. Other means have proven to be useful including slip clutches, brakes (proney or other) or electronically controlled devices such as motors etc.

Bringing our attention back to the rollers used for advancing the evaporant, it must be noted that the balance between friction needed to pull the material and feed it through the directing tube 22 and the sticking coefficient of the evaporant material itself to the wheel is critical. For example, Lithium metal, with and without alloying materials is both very soft and very sticky. It has been found that in order to reliably feed this material, wheels of a material possessing the properties of glass filled Teflon are necessary. The glass fibers provide traction and the matrix of Teflon provides release. Furthermore, it has been found that the coefficient of friction of the inside of the directing tube 22 is also critical to the units operation. It is necessary to use a material on the inner surface of this element that posses the combined properties of being stable at temperature and able to withstand the forces of the wire against the inside of the element and provide low friction to allow the material to properly be dispensed. For very soft or sticky material, It may be further necessary to nearly eliminate the amount of friction on the inside of the tube 22 by aligning the apparatus in a vertical orientation whereby the direction of the tube is nearly 90 degrees to the evaporation surface of the hot wall reactor. It will be noted that slots and spherical clamping elements are provided for this degree of freedom in mounting the apparatus. Clearly, any configuration of wheel and tube and material that provides this balance is also incorporated into this invention, be that traction is provided by machined or molded shapes in the outer surface of the wheel, or coatings of materials for release on metal or other wheel or tube materials.

Thus, as can be seen, the combination of parts and the combination of depositing materials suitable for solid state batteries and electrochemical devices is unique to this invention, particularly in its ability to reliably feed both solid and hollow core material to a suitable evaporation source. It should also be noted that an apparatus with all of these features is not available commercially, and thusly needed to be invented.

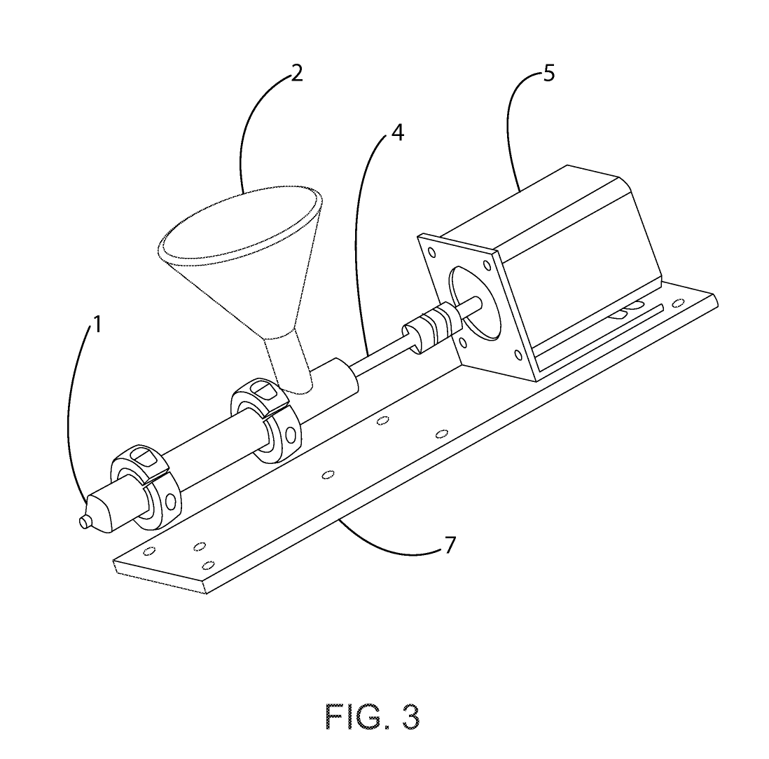

FIG. 3 illustrates a simplified diagram of an evaporant-delivering device according to an embodiment of the present invention.

Referring to FIG. 3, describing a preferred embodiment of the invention unique and particularly useful for delivering evaporant material whose calculated surface to volume ratio is in the medium range. As can be seen in figure three, this embodiment contains many elements common to figures one and two, noting in particular, the motor 5 and the rotary motion it imparts to the device. Additionally, further detail to FIG. 1 is shown in the large storage container 2 for holding and feeding evaporant material. New to this element and embodiment, made necessary by the different surface to volume ratio of the evaporant, is the use of a helical inclined plane.

This plain 4 is tightly fitted to barrel 1 and is turned by motor 5, mounted on platform 7, to precisely and repeatedly move evaporant from storage 2 to the evaporation source. Clearly this embodiment conserves the unique and important invented elements of the apparatus.

As can be imagined, once the details of this embodiment are understood, modifications may be incorporated such as the addition of shielding, directional tubes, increases or decreases in the diameter or length of the helical inclined plane and the like.

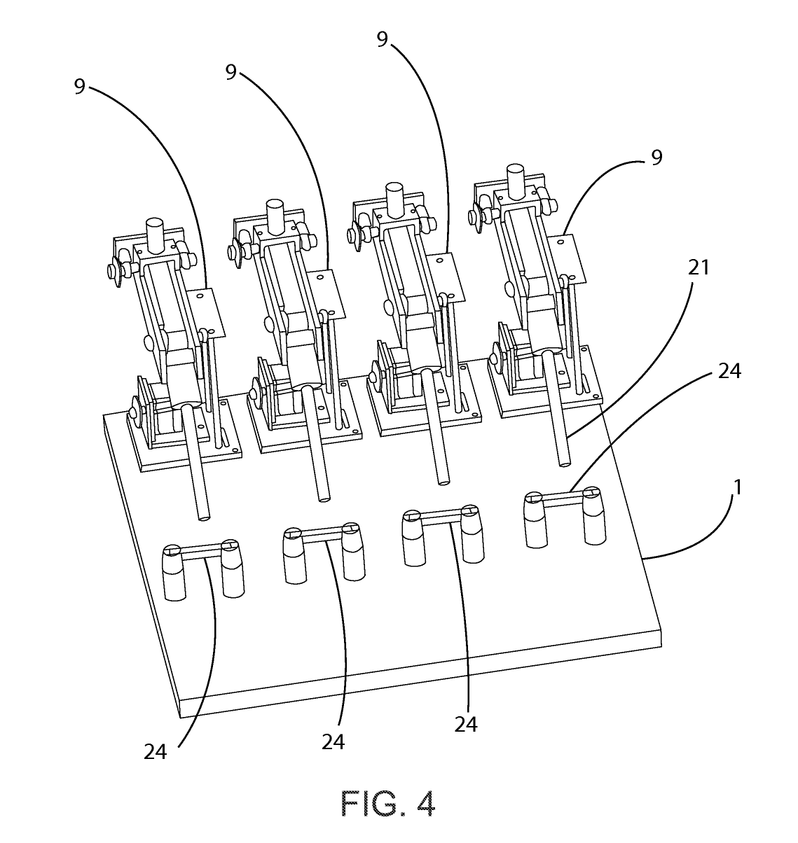

FIG. 4 illustrates a simplified diagram of an evaporant-delivering device according to an embodiment of the present invention.

Referring to FIG. 4, describing a preferred embodiment of the invention particularly unique and useful for delivering evaporant material over a wide area. As can be seen in figure four, this embodiment contains many elements common to the other preferred embodiments and may be understood to allow interchange of any apparatus amongst themselves in this element of the invention.

Incorporating additional detail to figures one though three, figure four illustrate the combination of multiple storage-meter-transport apparatuses 9 in this instance, arrayed in a line. Typically, this line would be oriented at 90 degrees to the motion of the substrate. Alternative alignments and elements include orientation at more than or less than 90 degrees to substrate motion up to 45 degrees in either direction. These apparatuses are arranged and fixed to substrate 1 as shown.

As described above, and hereby illustrated and further detailed, the use of different evaporant materials in each of the apparatus is envisioned. Moving further into the details of the apparatus, it is clear that one element of this embodiment features evaporation sources of resistance heated materials (24) arrayed to coincide with the apparatus. Although these evaporation sources are depicted in a line 90 degrees to the substrate motion, alternative alignments and elements include orientation at more than or less than 90 degrees to substrate motion up to 45 degrees in either direction. These apparatuses are arranged and fixed to substrate 1 as shown. As described above, these resistance heated sources may also be heated from a number of methods including but not limited to energy imparted by induction, impingement of energetic particles, lasers, plasmas, flames, and the like.

The combined plumes of evaporant from this array of apparatus constitutes a carefully calculated and empirically verified coverage area of the substrate to produce uniformity and rate of deposition of the thin films necessary for the manufacture of thin film electrochemical devices. This uniformity of deposition is governed by the 3 dimensional spacing of all components and the movement of the substrate.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. An apparatus for the manufacture of a solid state electrochemical device using a high speed evaporation process, the apparatus comprising:
a containment vessel for a metal oxide or other material, the material characterized in a fluid, bendable, meter-able, or dispensable form and characterized by an engineered surface to volume ratio;
a hot wall reactor region coupled to the containment vessel by a transport mechanism;
a process region positioned within a vicinity of the hot wall reactor region;
a work piece provided within the process region and coupled to a transfer device configured to move the work piece from a first region to a second region in a continuous or intermittent manner, the process region within a vicinity of the hot wall reactor to expose the work piece to the hot wall reactor; wherein the vicinity between the hot wall reactor and the work piece is about 10 cm to 1 meter;
a vacuum chamber or plurality of chambers in fluid communication with each other, configured to enclose the containment vessel, hot wall reactor region, process region, and the work piece within the process region; and
an energy source configured to the hot wall reactor to subject the material to thermal energy to substantially evaporate the material within a time period of about one second or less without decomposition into undesirable components and cause deposition of a desired gaseous species derived from the evaporated material onto a surface region of the work piece to form the cathode or cathode modification component of the solid state electrochemical device.

2. The apparatus of claim 1 wherein the specific cathode material is characterized by a mixture of cathode and anode material co-deposited so as to form a cathode layer in a partially or fully discharged state with the benefit of modified intercalation stresses;
wherein the engineered surface to volume ratio is provided by a predetermined controlled process.

3. The apparatus of claim 1 wherein the evaporation is characterized by a rate of about 10 to 10,000 Angstroms per second per 100 square centimeters; wherein the evaporated material may contain entrained non-reactive species in the shape of nano rods, cones, columns, fibers, spheres or the like, with or without binder, comprising a void or voided porous cathode or cathode modification layer.

4. The apparatus of claim 1 wherein the containment vessel comprises a plurality of containment vessels and the energy source comprises a plurality of respective energy sources which may be combined; wherein the containment vessels may be specific to different surface to volume ratio materials; and which materials may be mixtures of other materials; and
the combination of said containment vessels is suitable for producing co deposited or multi deposited materials, including graded materials for the cathode layer or cathode modification layer of an electrochemical device.

5. The apparatus of claim 1 further comprising a controller having a computer readable memory device, the computer readable memory device comprising a control module for feedback to monitor a rate of the evaporation of the material and cause formation of a thickness of material for the cathode layer of the device, the thickness of material ranging in uniformity from about 0.1% to about 5%; with the feedback device being selected from at least one of an optical reflection device, beta back scattering device, electron impact spectroscopy device, X-RAY fluorescence device, X-RAY diffraction device, micro balance device, optical emission device, or electro-magnetic-field induction device.

6. The apparatus of claim 1 further comprising a transfer device to move the material from the containment vessel to the hot wall reactor region and configured to move at a rate to maintain the material free from degradation into undesirable components and includes a transfer device of at least one of a screw or helical inclined plane type conveyer device, belt device, a roller device, a vibration or other energy transfer device, or a mechanical agitation device, the transfer device being configured to provide a smooth and interruption free arrival of material to the hot wall reactor including surface tension modifications of the transfer device, or force, the force being selected from at least one of compressive, magnetic, or electrostatic.

7. The apparatus of claim 1 further comprising a metering device coupled to the containment vessel to meter a selected amount of the material to the hot wall reactor region containing at least one of an orifice or weir, volume balance or volume measuring device, velocity balance or velocity measuring device, a mass balance or mass measuring device, a length balance or length measuring device, or a pressure balance or pressure measuring device;
wherein the metering device further comprising a doctor blade or blades.

8. The apparatus of claim 1 wherein the energy source of the hot wall reactor comprises at least a resistance, inductive, or a plurality of energetic particles as a heating source.

9. The apparatus of claim 1 wherein the hot wall reactor region comprises materials of one or more of the following: tungsten, molybdenum, tantalum, platinum, iridium, carbon, stainless and high nickel super alloys, ceramics including electrically conductive species such as silicon nitride, and non conductive species such as aluminum and zirconium oxides or layers thereof.

10. The apparatus of claim 1 further comprising a transfer chamber and a load lock, the transfer chamber being coupled to the vacuum chamber via the load lock, the transfer chamber being configured to input the material from an external region to the containment vessel while maintaining a vacuum in the vacuum chamber during operation of an evaporation process without interrupting the evaporation process in the vacuum chamber, the transfer chamber being configured to condition the material before input into the containment vessel, the condition including at least a degas process, the transfer chamber being isolated from the vacuum chamber via the load lock; which may include a sensing device to monitor and control an amount of the material within the transfer chamber.

11. The apparatus of claim 1 wherein the material within the transfer chamber comprises a desirable amount of material to process greater than 1000 electrochemical devices within a single vacuum cycle of the vacuum chamber.

12. The apparatus of claim 1 wherein the work piece is selected from a continuous roll of film, a belt or a drum device.

13. The apparatus of claim 1 further comprising a shaped mask device configured between the hot wall reactor region and the work piece, the shaped mask device may be coupled to a heating device to maintain the mask device essentially free from a residue from the complex metal oxide material and is so positioned as to allow either demarcation of the cathode material or oblique angle deposition for the formation of a void or voided porous like cathode or cathode modification layer.

14. The apparatus of claim 1 further comprising the utility to selectively remove substantially inert materials entrained in the deposited cathode or cathode modification layer by the application of heat, or energy in the form of laser, ion, reactive ion, plasma or reactive plasma.

15. The apparatus of claim 1 wherein the work piece is configured to sequentially deposit or multi-deposit, in a single motion, elements of the cathode or cathode modification layer of the electrochemical device.

16. An apparatus for the manufacture of a solid state electrochemical device using a high speed evaporation process, the apparatus comprising:
a containment vessel for an anode or other material, the material characterized in a fluid, bendable, meter-able, or dispensable form and characterized by an engineered surface to volume ratio;
a hot wall reactor region coupled to the containment vessel by a transport mechanism;
a process region positioned within a vicinity of the hot wall reactor region;
a work piece provided within the process region and coupled to a transfer device configured to move the work piece from a first region to a second region in a continuous or intermittent manner, the process region within a vicinity of the hot wall reactor to expose the work piece to the hot wall reactor; wherein the vicinity between the hot wall reactor and the work piece is about 10 cm to 1 meter;
a vacuum chamber or plurality of chambers in fluid communication with each other, configured to enclose the containment vessel, hot wall reactor region, process region, and the work piece within the process region; and
an energy source configured to the hot wall reactor to subject the material to thermal energy to substantially evaporate the material within a time period of about one second or less without decomposition into undesirable components and cause deposition of a desired gaseous species derived from the evaporated material onto a surface region of the work piece to form the anode or anode modification component of the solid state electrochemical device.

17. The apparatus of claim 16 wherein the specific anode material is characterized by a deposition method apparatus to produce a void or voided porous anode layer or anode modification layer with the benefit of modified intercalation stresses; wherein the evaporation is characterized by a rate of about 10 to 10,000 Angstroms per second per 100 square centimeters; and further comprising a controller having a computer readable memory device, the computer readable memory device comprising a control module for feedback to monitor a rate of the evaporation of the material and cause formation of a thickness of material for the anode or anode modification layer of the device, the thickness of material ranging in uniformity from about 0.1% to about 5%; with the feedback device being selected from at least one of an optical reflection device, beta back scattering device, electron impact spectroscopy device, X-RAY fluorescence device, X-RAY diffraction device, micro balance device, optical emission device, or electro-magnetic induction device; and further comprising a transfer device to move the material from the containment vessel to the hot wall reactor region and configured to move at a rate to maintain the material free from degradation into undesirable components.

18. An apparatus for the manufacture of a solid state electrochemical device using a high speed evaporation process, the apparatus comprising:
a containment vessel for an electrolyte or other material, the material characterized in a fluid, bendable, meter-able, or dispensable form and characterized by an engineered surface to volume ratio;
a hot wall reactor region coupled to the containment vessel by a transport mechanism;
a process region positioned within a vicinity of the hot wall reactor region;
a work piece provided within the process region and coupled to a transfer device configured to move the work piece from a first region to a second region in a continuous or intermittent manner, the process region within a vicinity of the hot wall reactor to expose the work piece to the hot wall reactor; wherein the vicinity between the hot wall reactor and the work piece is about 10 cm to 1 meter;
a vacuum chamber or plurality of chambers in fluid communication with each other, configured to enclose the containment vessel, hot wall reactor region, process region, and the work piece within the process region; and
an energy source configured to the hot wall reactor to subject the material to thermal energy to substantially evaporate the material within a time period of about one second or less without decomposition into undesirable components and cause deposition of a desired gaseous species derived from the evaporated material onto a surface region of the work piece to form the electrolyte or electrolyte modification component of the solid state electrochemical device.

19. The apparatus of claim 18 wherein the specific electrolyte material is characterized by a deposition method and apparatus to produce a void or voided porous electrolyte layer or electrolyte modification layer with the benefit of modified intercalation stresses; wherein the evaporation is characterized by a rate of about 10 to 10,000 Angstroms per second per 100 square centimeters; wherein the evaporated material may contain entrained non-reactive species in the shape of nano rods, cones, columns, fibers, spheres or the like, with or without binder, comprising a void or voided porous electrolyte or electrolyte modification layer;
wherein the engineered surface to volume ratio is provided by a controlled process.

20. The apparatus of claim 18 wherein the containment vessel comprises a plurality of containment vessels and the energy source comprises a plurality of respective energy sources; and further comprising a controller having a computer readable memory device, the computer readable memory device comprising a control module for feedback to monitor a rate of the evaporation of the material and cause formation of a thickness of material for the electrolyte or electrolyte modification layer of the device, the thickness of material ranging in uniformity from about 0.1% to about 5%; with the feedback device being selected from at least one of an optical reflection device, beta back scattering device, electron impact spectroscopy device , X-RAY fluorescence device, X-RAY diffraction device, micro balance device, optical emission device, or electro-magnetic induction device; and further comprising a metering device coupled to the containment vessel to meter a selected amount of the material to the hot wall reactor region containing at least one of the following: an orifice or weir, volume balance or volume measuring device, velocity balance or velocity measuring device, a mass balance or mass measuring device, a length balance or length measuring device, or a pressure balance or pressure measuring device, the metering device comprising a doctor blade or blades; wherein the material within the transfer chamber comprises a desirable amount of material to process greater than 1000 electrochemical devices within a single vacuum cycle of the vacuum chamber.
